(19) United States
(12) Patent Application Publication
(10) Pub. No.: US 2026/0293437 A1
(43) Pub. Date: Sep. 24, 2026

(54) DISPLAY DEVICE INCLUDING CLOCK LINK LINE

(71) Applicant: LG Display Co., Ltd., Seoul (KR)

(72) Inventors: Joo-Hwan KIM, Paju-si (KR); Seok-Young LEE, Paju-si (KR); Min-Kyoo KIM, Paju-si (KR)

(21) Appl. No.: 19/388,239

(22) Filed: Nov. 13, 2025

(30) Foreign Application Priority Data
Mar. 20, 2025 (KR) 10-2025-0036099

(51) Int. Cl. H10K 59/121; G09G 3/00; G09G 3/20; G09G 3/3233; H10K 59/131

(52) U.S. Cl. CPC H10K 59/1213; G09G 3/035; G09G 3/2092; G09G 3/3233; H10K 59/131; G09G 2300/0819; G09G 2300/0842; G09G 2300/0861; G09G 2310/0286; G09G 2310/08; G09G 2320/043

(57) ABSTRACT

A display device including: a timing controlling unit; a data driving unit; a gate driving unit; a first clock link line; an inverter; and a display panel having a display area and a non-display area surrounding the display area. The non-display area includes a bending area as a reference of folding, the timing controlling unit and the data driving unit are disposed in the non-display area at an upper portion of the bending area, the gate driving unit and the inverter are disposed in the non-display area at a lower portion of the bending area, and the first clock link line extends from the non-display area at the upper portion of the bending area to the non-display area at the lower portion of the bending area through the bending area.

### CROSS REFERENCE TO RELATED APPLICATION

This application claims priority from and the benefit of Korean Patent Application No. 10-2025-0036099, filed on Mar. 20, 2025, which is hereby incorporated by reference for all purposes as if fully set forth herein.

### BACKGROUND

### FIELD

Embodiments of the invention relate generally to a display device, and more particularly, to a display device including a clock link line.

### DISCUSSION OF THE BACKGROUND

Recently, various flat panel display devices, such as a liquid crystal display device (LCD), an organic light emitting diode (OLED) display device, and a field emission display (FED) device having excellent properties of a thin profile, a light weight, and a low power consumption, have been developed and applied to various fields.

In the display device, a clock signal is transmitted from a plurality of pads in a non-display area to a gate driving unit in the non-display area through a plurality of clock link lines in the non-display area.

In a small-sized display device, such as a watch, a driving unit is not connected to a display panel using a connection means, such as a flexible printed circuit (FPC). Instead, to minimize a volume, after the driving unit is mounted directly on the display panel, the display panel is folded such that the driving unit is disposed under a rear surface of the display panel.

For a folding substrate, the non-display area of the substrate of the display panel includes a bending area. However, when the substrate is folded, the plurality of clock link lines in the bending area may have deterioration, such as a crack. As a result, the clock signal is not transmitted to the gate driving unit and the gate driving unit operates abnormally.

The above information disclosed in this Background section is only for understanding of the background of the inventive concepts, and, therefore, it may contain information that does not constitute prior art.

### SUMMARY

Display devices according to embodiments of the invention are capable of substantially obviating one or more of the problems due to limitations and disadvantages of the related art.

Additional features of the inventive concepts will be set forth in the description which follows, and in part will be apparent from the description, or may be learned by practice of the inventive concepts.

According to one or more embodiments of the invention, a display device includes: a timing controller configured to generate an image data, a data control signal, and a gate control signal; a data driver configured to generate a data signal using the image data and the data control signal; a gate driver configured to generate a gate signal using the gate control signal; a first clock link line transmitting a first clock signal from the timing controller to the gate driver; an inverter configured to generate a second clock signal by inverting the first clock signal and to transmit the second clock signal to the gate driver; and a display panel displaying an image using the data signal and the gate signal and having a display area and a non-display area surrounding the display area. The non-display area includes a bending area as a reference of folding, wherein the timing controller and the data driver are disposed in the non-display area at an upper portion of the bending area, wherein the gate driver and the inverter are disposed in the non-display area at a lower portion of the bending area, and wherein the first clock link line extends from the non-display area at the upper portion of the bending area to the non-display area at the lower portion of the bending area through the bending area.

The display device may further include a first clock line transmitting the first clock signal to the gate driver; and a second clock line transmitting the second clock signal to the gate driver.

The inverter may be disposed between the bending area and the gate driver; the first clock link line may be connected to an input terminal of the inverter and a first end of the first clock line; and a first end of the second clock line may be connected to an output terminal of the inverter.

The inverter may be disposed at a lower portion of the gate driver; the first clock link line may be connected to a first end of the first clock line; a second end of the first clock line may be connected to an input terminal of the inverter; and a first end of the second clock line may be connected to an output terminal of the inverter.

The display device may further include a second clock link line transmitting the first clock signal from the timing controller to the gate driver; and the second clock link line may extend from an upper portion of the bending area to the non-display area at a lower portion of the bending area through the bending area.

The inverter may be disposed between the bending area and the gate driver; the first and second clock link lines are connected to an input terminal of the inverter and a first end of the first clock line; and a first end of the second clock line is connected to an output terminal of the inverter.

The display panel may include a plurality of subpixels in the display area, wherein each of the plurality of subpixels includes: a first transistor switched according to a voltage of a first node and connected to second and third nodes; a second transistor switched according to a first scan signal and connected to the first and second nodes; a third transistor switched according to a second scan signal and connected to the third node and the data signal; a fourth transistor switched according to a second emission signal and connected to the second node and a high level signal; a fifth transistor switched according to a first emission signal and connected to the third node and a fourth node; a sixth transistor switched according to the first emission signal and connected to the fourth node and an initial signal; a storage capacitor connected to the first and fourth nodes; and a light emitting diode connected to the fourth node and a low level signal.

A gate electrode of the first transistor, a source electrode of the second transistor and a first capacitor electrode of the storage capacitor may constitute the first node; a drain electrode of the first transistor, a drain electrode of the second transistor and a drain electrode of the fourth transistor may constitute the second node; a source electrode of the first transistor, a source electrode of the third transistor and a source electrode of the fifth transistor may constitute the third node; and a drain electrode of the fifth transistor, a drain electrode of the sixth transistor and a second capacitor electrode of the storage capacitor may constitute the fourth node.

The gate signal may include a first scan signal, a second scan signal, a first emission signal, and a second emission signal, wherein the gate driver may include first and second gate drivers at both side portions of the display panel; the first gate driver may include a second scan block configured to generate the second scan signal and a second emission block configured to generate the second emission signal; and the second gate driver may include a first scan block configured to generate the first scan signal and a first emission block configured to generate the first emission signal.

The second scan block may include a first stage transistor switched according to a voltage of a Q node and connected to the first clock signal and a second stage transistor, the second stage transistor switched according to a voltage of a QB node and connected to the first stage transistor and a gate high voltage; a third stage transistor switched according to the second clock signal and connected to one of a start signal and an (n-1)th second scan signal and a Q2 node; a fourth stage transistor switched according to the first clock signal and connected to the Q2 node and a fifth stage transistor, the fifth stage transistor switched according to the voltage of the QB node and connected to fourth stage transistor and the gate high voltage; a sixth stage transistor switched according to the second clock signal and connected to a gate low voltage and the QB node; a seventh stage transistor switched according to a voltage of the Q2 node and connected to the second clock signal and the QB node; and an eighth stage transistor switched according to the gate low voltage and connected to the Q2 node and the Q node.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a view showing a display device according to a first embodiment of the invention.

FIG. 2 is a circuit diagram showing a subpixel of a display device according to a first embodiment of the invention.

FIG. 3 is a timing chart showing a plurality of gate signals supplied to a subpixel of a display device according to a first embodiment of the invention.

FIG. 4 is a block diagram showing first and second gate driving units and a display panel of a display device according to a first embodiment of the invention.

FIG. 5 is a view showing a shift register of a gate driving unit of a display device according to a first embodiment of the invention.

FIG. 6 is a circuit diagram showing a stage of a shift register of a gate driving unit of a display device according to a first embodiment of the invention.

FIG. 7 is a timing chart showing a plurality of signals of a stage of a shift register of a gate driving unit of a display device according to a first embodiment of the invention.

FIG. 8 is a view showing a shift register of a gate driving unit of a display device according to a second embodiment of the invention.

FIG. 9 is a view showing a shift register of a gate driving unit of a display device according to a third embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In the following description, where the detailed description of the relevant known function or configuration may unnecessarily obscure a feature or aspect of the invention, a detailed description of such known function or configuration may be omitted or a brief description may be provided.

In construing an element, the element is to be construed as including an error or a tolerance range even where no explicit description of such an error or tolerance range is provided.

Although the terms "first," "second," A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the invention.

The term "display device" may include a display device in a narrow sense such as liquid crystal module (LCM), an organic light emitting diode (OLED) module and a quantum dot (QD) module including a display panel and a driving unit for driving the display panel. In addition, the term "display device" may include a complete product (or a final product) including the LCM, the OLED module or the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device according to an embodiment of the invention may include an applied product or a set device of a final user's device including the LCM, the OLED module or the QD module as well as a display device in a narrow sense such as the LCM, the OLED module or the QD module.

According to circumstances, the LCM, the OLED module or the QD module having a display panel and a driving unit may be expressed as "a display device", and an electronic apparatus of a complete product including the LCM, the OLED module or the QD module may be expressed as "a set device." For example, a display device in a narrow sense may include a display panel of a liquid crystal, an organic light emitting diode or a quantum dot and a source printed circuit board (PCB) of a control unit for driving the display panel, and a set device may further include a set PCB of a set control unit electrically connected to the source PCB for controlling the entire set device.

The display panel according to an embodiment of the invention may include all kinds of display panels such as a liquid crystal display panel, an organic light emitting diode display panel, a quantum dot display panel and an electroluminescent display panel. The display panel according to an embodiment of the invention is not limited to a specific display panel of a bezel bending having a flexible substrate for an organic light emitting diode display panel and a lower back plate supporter. A shape or a size of the display panel for the display device according to an embodiment of the invention is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor according to an embodiment of the invention may include one of an oxide thin film transistor, an amorphous silicon thin film transistor, and a low temperature polycrystalline silicon thin film transistor.

Features of various embodiments of the invention may be partially or entirely coupled to or combined with each other. They may be linked and operated technically in various ways as those skilled in the art may sufficiently understand. The aspects may be carried out independently of or in association with each other in various combinations.

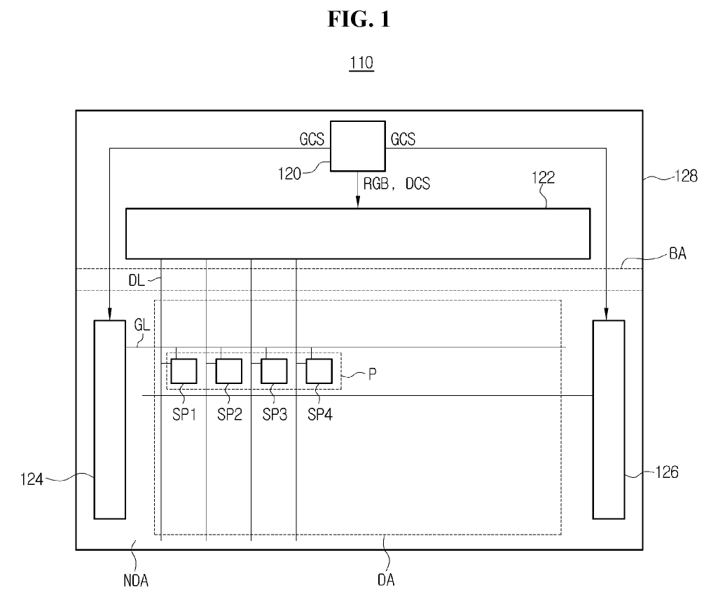

FIG. 1 is a view showing a display device according to a first embodiment of the invention. Although the display device may be an organic light emitting diode (OLED) display device, it is not limited thereto. For example, the display device may be a quantum dot display device, a micro light emitting diode (LED) display device or a mini light emitting diode (LED) display device.

In FIG. 1, a display device 110 according to a first embodiment of the invention includes a timing controlling unit 120 (e.g., a circuit), a data driving unit 122 (e.g., a circuit), first and second gate driving units 124 and 126 (e.g., circuits), and a display panel 128.

The timing controlling unit 120 generates an image data RGB, a data control signal DCS, and a gate control signal GCS using an image signal and a plurality of timing signals including a data enable signal, a horizontal synchronization signal, a vertical synchronization signal, and a clock signal transmitted from an external system, such as a graphic card or a television system.

The timing controlling unit 120 transmits the image data RGB and the data control signal DCS to the data driving unit 122, and transmits the gate control signal GCS to the first and second gate driving units 124 and 126.

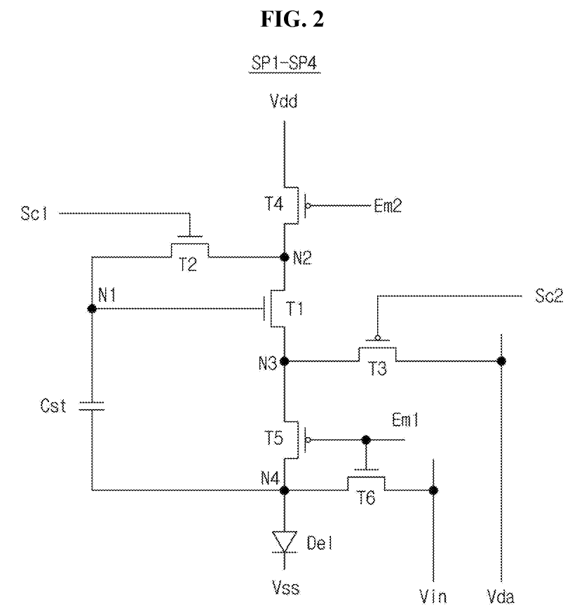

The data driving unit 122 generates a data signal (a data voltage) Vda (FIG. 2) using the image data RGB and the data control signal DCS transmitted from the timing controlling unit 120, and applies the data signal Vda to a data line DL of the display panel 128.

The first and second gate driving units 124 and 126 generate a gate signal (a gate voltage) Sc1, Sc2, Em1, and Em2 (FIG. 2) using the gate control signal GCS transmitted from the timing controlling unit 120 and applies the gate signal Sc1, Sc2, Em1, and Em2 to a gate line GL of the display panel 128.

The first and second gate driving units 124 and 126 may have a gate-in-panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Sc1, Sc2, Em1, and Em2 and the data signal Vda. Hereinafter, the gate signal Sc1, Sc2, Em1, and Em2 may be referred to as a scan1 signal Sc1, a scan2 signal Sc2, an emission1 signal Em1, and an emission2 signal Em2.

For displaying an image, the display panel 128 includes a plurality of pixels P, a plurality of gate lines GL, and a plurality of data lines DL in the display area DA.

Each of the plurality of pixels P includes first, second, third, and fourth subpixels SP1, SP2, SP3, and SP4, and the gate line GL and the data line DL cross each other to define the first, second, third, and fourth subpixels SP1, SP2, SP3 and SP4. Each of the first, second, third, and fourth subpixels SP1, SP2, SP3, and SP4 is connected to the gate line GL and the data line DL.

For example, the first, second, third, and fourth subpixels SP1, SP2, SP3, and SP4 may correspond to red, green, blue, and white colors, respectively.

In another embodiment, each of the plurality of pixels P includes first, second, and third subpixels SP1, SP2, and SP3 corresponding to red, green, and blue colors, respectively.

Each of the first, second, third, and fourth subpixels SP1, SP2, SP3, and SP4 may include a plurality of transistors, such as first to sixth transistors T1 to T6 (FIG. 2), a storage capacitor Cst (FIG. 2), and a light emitting diode Del (FIG. 2).

After the display panel 128 is fabricated, the timing controlling unit 120 and the data driving unit 122 are mounted in the non-display area NDA on a substrate of the display panel 128. Next, a portion of the substrate of the display panel 128 where the timing controlling unit 120 and the data driving unit 122 are mounted is folded such that the timing controlling unit 120 and the data driving unit 122 are disposed under a rear surface of the display panel 128 to complete the display device 110.

The non-display area NDA of the display panel 128 includes a bending area BA as a reference of folding. For example, the substrate corresponding to the bending area BA may include a flexible substrate of a flexible material, such as polyimide (PI), and the substrate corresponding to a portion other than the bending area BA may include a flexible substrate of a plastic, such as polyimide (PI) and a back plate of a rigid material such as invar (nickel-iron alloy).

A structure of each subpixel SP1 to SP4 of the display device 110 will be illustrated with reference to FIG. 2, which is a circuit diagram showing a subpixel of a display device according to a first embodiment of the invention.

In FIG. 2, each of the first, second, third, and fourth subpixels SP1, SP2, SP3, and SP4 of the display panel 128 of the display device 110 according to a first embodiment of the invention includes first to sixth transistors T1 to T6, a storage capacitor Cst, and a light emitting diode Del. At least one of the first to sixth transistors T1 to T6 may be an oxide semiconductor thin film transistor, and the others of the first to sixth transistors T1 to T6 may be a low temperature polycrystalline silicon thin film transistor.

For example, the first, third, fourth, and fifth transistors T1, T3, T4, and T5 may be a negative (N) type low temperature polycrystalline silicon thin film transistor or a positive (P) type low temperature polycrystalline silicon thin film transistor, and the second and sixth transistors T2 and T6 may be a negative (N) type oxide semiconductor thin film transistor.

The first transistor T1 as a driving transistor is switched according to a voltage of a first capacitor electrode of the storage capacitor Cst. A gate electrode of the first transistor T1 is connected to a first node N1, a source electrode of the first transistor T1 is connected to a third node N3, and a drain electrode of the first transistor T1 is connected to a second node N2.

The second transistor T2 as a sensing transistor is switched according to a scan1 signal Sc1. A gate electrode of the second transistor T2 is connected to the scan1 signal Sc1, a source electrode of the second transistor T2 is connected to the first node N1, and a drain electrode of the second transistor T2 is connected to the second node N2.

The third transistor T3 as a switching transistor is switched according to a scan2 signal Sc2. A gate electrode of the third transistor T3 is connected to the scan2 signal Sc2 a source electrode of the third transistor T3 is connected to the third node N3, and a drain electrode of the third transistor T3 is connected to the data signal Vda.

The fourth transistor T4 as an emitting transistor is switched according to an emission2 signal Em2. A gate electrode of the fourth transistor T4 is connected to the emission2 signal Em2, a source electrode of the fourth transistor T4 is connected to a high level signal (high level voltage, e.g., high potential voltage) Vdd, and a drain electrode of the fourth transistor T4 is connected to the second node N2.

The fifth transistor T5 as an emitting transistor is switched according to an emission1 signal Em1. A gate electrode of the fifth transistor T5 is connected to the emission1 signal Em1, a source electrode of the fifth transistor T5 is connected to the third node N3, and a drain electrode of the fifth transistor T5 is connected to a fourth node N4.

The sixth transistor T6 as an initializing transistor is switched according to the emission1 signal Em1. A gate electrode of the sixth transistor T6 is connected to the emission1 signal Em1, a source electrode of the sixth transistor T6 is connected to an initial signal (initial voltage) Vin, and a drain electrode of the sixth transistor T6 is connected to the fourth node N4.

The storage capacitor Cst stores the data signal Vda and a threshold voltage Vth of the first transistor T1. A first capacitor electrode of the storage capacitor Cst is connected to the first node N1, and a second capacitor electrode of the storage capacitor Cst is connected to the fourth node N4.

The light emitting diode Del is connected between the fourth node N4 and the low level signal (low level voltage, e.g., low potential voltage) Vss to emit a light of a luminance proportional to a current of the first transistor T1. An anode of the light emitting diode Del is connected to the fourth node N4, and a cathode of the light emitting diode Del is connected to the low level signal Vss.

The gate electrode of the first transistor T1, the source electrode of the second transistor T2, and the first capacitor electrode of the storage capacitor Cst constitute the first node N1, and the drain electrode of the first transistor T1, the drain electrode of the second transistor T2, and the drain electrode of the fourth transistor T4 constitute the second node N2. The source electrode of the first transistor T1, the source electrode of the third transistor T3, and the source electrode of the fifth transistor T5 constitute the third node N3, and the drain electrode of the fifth transistor T5, the drain electrode of the sixth transistor T6, and the second capacitor electrode of the storage capacitor Cst constitute the fourth node N4.

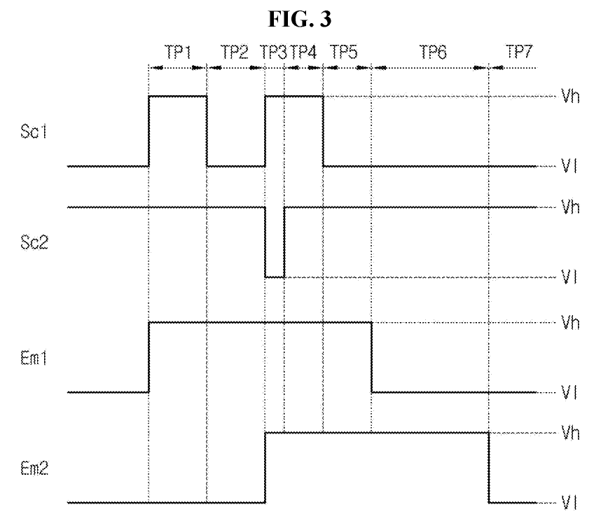

An operation of each subpixel SP1 to SP4 of the display device 110 will be illustrated with reference to FIG. 3, which is a timing chart showing a plurality of gate signals supplied to a subpixel of a display device according to a first embodiment of the invention.

In FIG. 3, during a first period TP1 as an initializing period, the scan1 signal Sc1, the scan2 signal Sc2 and the emission1 signal Em1 have a logic high voltage Vh, and the emission2 signal Em2 has a logic low voltage Vl. As a result, the second, fourth, and sixth transistors T2, T4, and T6 are turned on, and the third and fifth transistors T3 and T5 are turned off. Accordingly, the first transistor T1 is turned on, the high level signal Vdd is applied to the first, second, and third nodes N1, N2, and N3, and the initial signal Vin is applied to the fourth node N4.

During a second period TP2 as a holding period, the scan2 signal Sc2 and the emission1 signal Em1 have a logic high voltage Vh, and the scan1 signal Sc1 and the emission2 signal Em2 have a logic low voltage Vl. As a result, the second and sixth transistors T2 and T6 are turned on, and the second, third, and fifth transistors T2, T3, and T5 are turned off. Accordingly, the first transistor T1 is turned on, the high level signal Vdd of the first, second, and third nodes N1, N2, and N3 is maintained, and the initial signal Vin is applied to the fourth node N4.

During a third period TP3 as a sampling period, the scan1 signal Sc1, the emission1 signal Em1, and the emission2 signal Em2 have a logic high voltage Vh, and the scan2 signal Sc2 has a logic low voltage Vl. As a result, the second, third, and sixth transistors T2, T3, and T6 are turned on, and the fourth and fifth transistors T4 and T5 are turned off. Accordingly, the first transistor T1 is turned on, the data signal Vda is applied to the second and third nodes N2 and N3, and the initial signal Vin is applied to the fourth node N4.

Here, when a voltage of the gate electrode of the first transistor T1 is reduced from the high level signal Vdd to become a sum (Vda+Vth) of the data signal Vda and the threshold voltage (Vth), the first transistor T1 is turned off, and the sum (Vda+Vth) of the data signal Vda and the threshold voltage (Vth) is stored in the first capacitor electrode of the storage capacitor Cst.

During a fourth period TP4 as a holding period, the scan1 signal Sc1, the scan2 signal Sc2, the emission1 signal Em1 and the emission2 signal Em2 have a logic high voltage Vh. As a result, the second and sixth transistors T2 and T6 are turned on, and the third, fourth, and fifth transistors T3, T4 and T5 are turned off. Accordingly, the first transistor T1 is turned off, the sum (Vda+Vth) of the data signal Vda and the threshold voltage (Vth) of the first node N1 is maintained, the data signal Vda of the second and third nodes N2 and N3 is maintained, and the initial signal Vin is applied to the fourth node N4.

During a fifth period TP5 as a holding period, the scan2 signal Sc2, the emission1 signal Em1 and the emission2 signal Em2 have a logic high voltage Vh, and the scan1 signal Sc1 has a logic low voltage Vl. As a result, the sixth transistor T6 is turned on, and the second, third, fourth, and fifth transistors T2, T3, T4, and T5 are turned off. Accordingly, the first transistor T1 is turned off, the sum (Vda+Vth) of the data signal Vda and the threshold voltage (Vth) of the first node N1 is maintained, the data signal Vda of the second and third nodes N2 and N3 is maintained, and the initial signal Vin is applied to the fourth node N4.

During a sixth period TP6 as an initializing period, the scan2 signal Sc2 and the emission2 signal Em2 have a logic high voltage Vh, and the scan1 signal Sc1 and the emission1 signal Em1 have a logic low voltage Vl. As a result, the fifth transistor T5 is turned on, and the second, third, fourth, and sixth transistors T2, T3, T4, and T6 are turned off. Accordingly, the first transistor T1 is turned off, the sum (Vda+Vth) of the data signal Vda and the threshold voltage (Vth) of the first node N1 is maintained, the data signal Vda of the second and third nodes N2 and N3 is maintained, and the data signal Vda is applied to the fourth node N4.

During a seventh period TP7 as an emitting period, the scan2 signal Sc2 has a logic high voltage Vh, and the scan1 signal Sc1, the emission1 signal Em1, and the emission2 signal Em2 have a logic low voltage Vl. As a result, the fourth and fifth transistors T4 and T5 are turned on, and the second, third and sixth transistors T2, T3 and T6 are turned off. Accordingly, the first transistor T1 is turned on, a current corresponding to the data signal Vda flows through the first transistor T1, and the light emitting diode Del emits a light of a luminance corresponding to the data signal Vda.

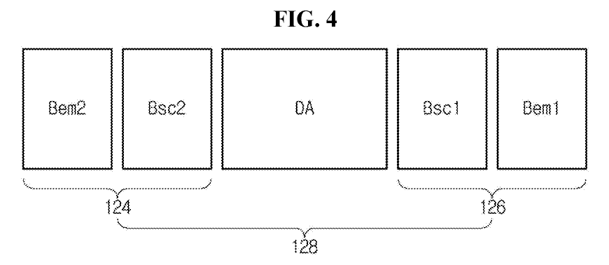

A structure of the first and second gate driving units 124 and 126 of the display device 110 will be illustrated with reference to FIG. 4, which is is a block diagram showing first and second gate driving units and a display panel of a display device according to a first embodiment of the invention.

In FIG. 4, the first gate driving unit 124 of the display device 110 according to a first embodiment of the invention includes a scan2 block Bsc2 and an emission2 block Bem2, and the second gate driving unit 126 of the display device 110 according to a first embodiment of the invention includes a scan1 block Bsc1 and an emission1 block Bem1. The display area DA of the display panel 128 is disposed between the first and second gate driving units 124 and 126.

In another embodiment, the disposition structure of the scan1 block Bsc1, the scan2 block Bsc2, the emissoin1 block Bem1, and the emission2 block Bem2 in the first and second gate driving units 124 and 126 may be variously changed.

For example, the emission2 block Bem2 may be disposed farther from the display area DA than the scan2 block Bsc2, and the emission1 block Bem1 may be disposed farther from the display area DA than the scan1 block Bsc1 in a first embodiment of FIG. 4. In another embodiment, the scan2 block Bsc2 may be disposed farther from the display area DA than the emission2 block Bem2, and the scan1 block Bsc1 may be disposed farther from the display area DA than the emission1 block Bem1.

Each of the scan2 block Bsc2 and the emission2 block Bem2 of the first gate driving unit 124 and the scan1 block Bsc1 and the emission1 block Bem1 of the second gate driving unit 126 may be one stage of a shift register, and the shift register may include a plurality of stages connected to each other in a cascade type.

In the first gate driving unit 124, the scan2 block Bsc2 and the emission2 block Bem2 generate the scan2 signal Sc2 (FIG. 2) and the emission2 signal Em2 (FIG. 2), respectively.

In the second gate driving unit 126, the scan1 block Bsc1 and the emission1 block Bem1 generate the scan1 signal Sc1 (FIG. 2) and the emission1 signal Em1 (FIG. 2), respectively.

The scan1 signal Sc1 of the scan1 block Bsc1 is supplied to the second transistor T2 (FIG. 2) in each subpixel SP1 to SP4 of the display area DA through the gate line GL, and the scan2 signal Sc2 of the scan2 block Bsc2 is supplied to the third transistor T3 (FIG. 2) in each subpixel SP1 to SP4 of the display area DA through the gate line GL.

The emission1 signal Em1 of the emission1 block Bem1 is supplied to the fifth and sixth transistors T5 and T6 (FIG. 2) in each subpixel SP1 to SP4 of the display area DA through the gate line GL, and the emission2 signal Em2 of the emission2 block Bem2 is supplied to the fourth transistor T4 (FIG. 2) in each subpixel SP1 to SP4 of the display area DA through the gate line GL.

In another embodiment, the first and second gate driving units 124 and 126 may have a symmetric structure. For example, each of the first and second gate driving units 124 and 126 may include the scan1 block Bsc1, the scan2 block Bsc2, the emission1 block Bem1. and the emission2 block Bem2.

The scan2 block Bsc2 generates the scan2 signal Sc2 using first and second clock signals.

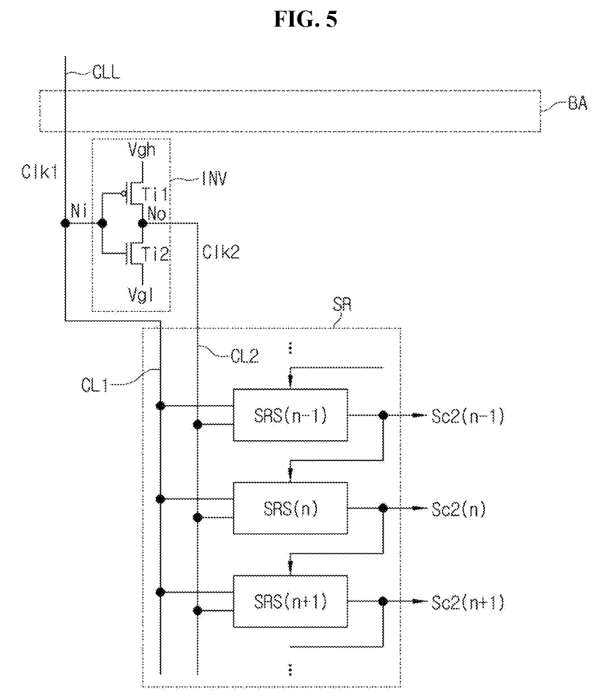

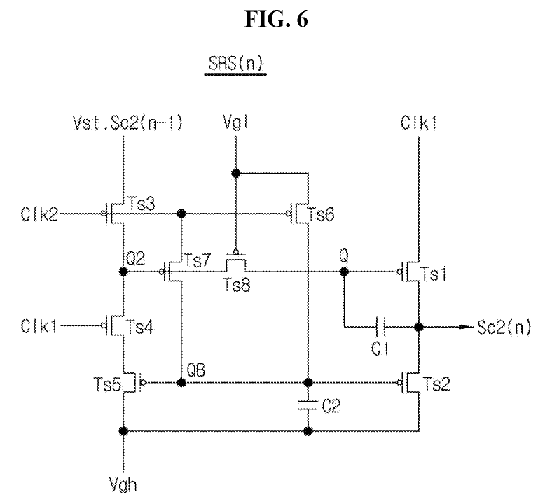

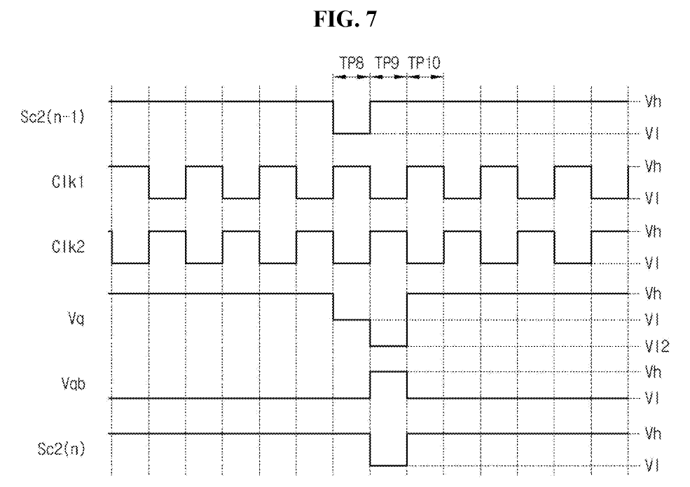

FIG. 5 is a view showing a shift register of a gate driving unit of a display device according to a first embodiment of the invention; FIG. 6 is a circuit diagram showing a stage of a shift register of a gate driving unit of a display device according to a first embodiment of the invention; and FIG. 7 is a timing chart showing a plurality of signals of a stage of a shift register of a gate driving unit of a display device according to a first embodiment of the invention.

In FIGS. 1 and 5, the first gate driving unit 124 is disposed in the non-display area NDA of the display device 110 according to a first embodiment of the invention. The first gate driving unit 124 includes a shift register SR generating the scan2 signal Sc2, and the shift register SR includes a plurality of stages SRS(n-1), SRS(n) and SRS(n+1) connected to each other in a cascade type.

Each of the plurality of stages SRS(n-1), SRS(n) and SRS(n+1) sequentially generates a plurality of scan2 signals Sc2(n-1), Sc2(n) and Sc2(n+1) using first and second clock signals Clk1 and Clk2, a start signal Vst (FIG. 6) or the scan2 signal Sc2(n-1), Sc2(n) and Sc2(n+1) as an output signal of a previous stage, a gate high voltage Vgh and a gate low voltage Vgland transmits the plurality of scan2 signals Sc2(n-1), Sc2(n) and Sc2(n+1) to the third transistor T3 of each subpixel SP1 to SP4 of the display panel 128.

For example, an (n)th stage SRS(n) may generate an (n)th scan2 signal Sc2(n) using an (n-1)th scan2 signal Sc2(n-1) as an output signal of an (n-1)th stage SRS(n-1), the gate high voltage Vgh and the gate low voltage Vgl and may apply the (n)th scan2 signal Sc2(n) to the gate electrode of the third transistor T3 of each subpixel SP1 to SP4 of an (n)th horizontal pixel line of the display panel 128.

Here, an inverter INV is disposed in the non-display area NDA between the shift register SR of the first gate driving unit 124 and the bending area BA, and the inverter INV includes first and second inverter transistors Ti1 and Ti2.

The first inverter transistor Ti1 is a positive (P) type. A gate electrode of the first inverter transistor Ti1 is connected to an input terminal Ni of the inverter INV, a source electrode of the first inverter transistor Ti1 is connected to the gate high voltage Vgh, and a drain electrode of the first inverter transistor Ti1 is connected to an output terminal No of the inverter INV.

The second inverter transistor Ti2 is a negative (N) type. A gate electrode of the second inverter transistor Ti2 is connected to the input terminal Ni of the inverter INV, a source electrode of the second inverter transistor Ti2 is connected to the gate low voltage Vgl, and a drain electrode of the second inverter transistor Ti2 is connected to the output terminal No of the inverter INV.

The inverter INV generates the second clock signal Clk2 having an inverted shape of the first clock signal Clk1 using the first clock signal Clk1 transmitted from the timing controlling unit 120 through a clock link line CLL and a first clock line CL1 and transmits the second clock signal Clk2 to the plurality of stages SRS(n-1), SRS(n) and SRS(n+1) of the shift register SR through a second clock line CL2.

The clock link line CLL connected to the timing controlling unit 120 extends to the inverter INV through the bending area BA to be connected to the input terminal Ni of the inverter INV and a first end of the first clock line CL1.

The first clock line CL1 connected to the clock link line CLL1 extends along a side portion of the shift register SR to be connected to each of the plurality of stages SRS(n-1), SRS(n) and SRS(n+1).

As a result, the first clock signal Clk1 of the timing controlling unit 120 is supplied to the plurality of stages SRS(n-1), SRS(n) and SRS(n+1) of the shift register SR through the clock link line CLL and the first clock line CL1.

Further, the first clock signal Clk1 of the timing controlling unit 120 is supplied to the inverter INV through the clock link line CLL and the first clock line CL1. The inverter INV generates the second clock signal Clk2 by inverting the first clock signal Clk1, and the second clock signal Clk2 of the inverter INV is supplied to the plurality of stages SRS(n-1), SRS(n) and SRS(n+1) of the shift register SR through the second clock line CL2.

Since only one clock link line CLL is disposed in the bending area BA for supplying the first clock signal Clk1 to the inverter INV and the shift register SR, a probability of deterioration such as a crack of the clock link line CLL in the bending area BA is reduced while the substrate is folded.

In FIG. 6, the (n)th stage SRS(n) (corresponding to the scan2 block Bsc2 of FIG. 4) of the shift register SR of the first gate driving unit 124 of the display device 110 according to a first embodiment of the invention includes first to eighth stage transistors Ts1 to Ts8 and first and second capacitors C1 and C2.

For example, the first to eighth stage transistors Ts1 to Ts8 may be a positive (P) type, and it is not limited thereto.

The first stage transistor Ts1 is switched according to a voltage of a Q node Q to output the first clock signal Clk1 as the (n)th scan2 signal Sc2(n), and the second stage transistor Ts2 is switched according to a voltage of a QB node QB to output the gate high voltage as the (n)th scan2 signal Sc2(n).

A gate electrode of the first stage transistor Ts1 is connected to the Q node Q, a source electrode of the first stage transistor Ts1 is connected to the first clock signal Clk1, and a drain electrode of the first stage transistor Ts1 is connected to a source electrode of the second stage transistor Ts2.

A gate electrode of the second stage transistor Ts2 is connected to the QB node QB, a source electrode of the second stage transistor Ts2 is connected to the drain electrode of the first stage transistor Ts1, and a drain electrode of the second stage transistor Ts2 is connected to the gate high voltage Vgh.

The third stage transistor Ts3 is switched according to the second clock signal Clk2 to transmit the start signal Vst or the (n-1)th scan2 signal Sc2(n-1) to a Q2 node Q2 between the third and fourth stage transistors Ts3 and Ts4. The fourth stage transistor Ts4 is switched according to the first clock signal Clk1 to transmit a voltage of a connection node between the fourth and fifth stage transistors Ts4 and Ts5 to the Q2 node Q2. The fifth stage transistor Ts5 is switched according to a voltage of the QB node QB to transmit the gate high voltage Vgh to a connection node between the fourth and fifth stage transistors Ts4 and Ts5.

A gate electrode of the third stage transistor Ts3 is connected to the second clock signal Clk2, a source electrode of the third stage transistor Ts3 is connected to the start signal Vst or the (n-1)th scan2 signal Sc2(n-1), and a drain electrode of the third stage transistor Ts3 is connected to a source electrode of the fourth stage transistor TTs4, a gate electrode of the seventh stage transistor Ts7 and a source electrode of the eighth stage transistor Ts8.

A gate electrode of the fourth stage transistor Ts4 is connected to the first clock signal Clk1, a source electrode of the fourth stage transistor Ts4 is connected to a drain electrode of the third stage transistor Ts3, a gate electrode of the seventh stage transistor Ts7, and a source electrode of the eighth stage transistor Ts8, and a drain electrode of the fourth stage transistor Ts4 is connected to a source electrode of the fifth stage transistor Ts5.

A gate electrode of the fifth stage transistor Ts5 is connected to the QB node QB, a source electrode of the fifth stage transistor Ts5 is connected to a drain electrode of the fourth stage transistor Ts4, and a drain electrode of the fifth stage transistor Ts5 is connected to the gate high voltage Vgh.

The sixth stage transistor Ts6 is switched according to the second clock signal Clk2 to transmit the gate low voltage Vgl to the QB node QB. The seventh stage transistor Ts7 is switched according to a voltage of the Q2 node Q2 between the third and fourth stage transistors Ts3 and Ts4 to transmit the second clock signal Clk2 to the QB node QB. The eighth stage transistor Ts8 is switched according to the gate low voltage Vgl to transmit a voltage of the Q2 node Q2 between the third and fourth stage transistors Ts3 and Ts4 to the Q node Q.

A gate electrode of the sixth stage transistor Ts6 is connected to the second clock signal Clk2, a source electrode of the sixth stage transistor Ts6 is connected to the gate low voltage Vgl, and a drain electrode of the sixth stage transistor Ts6 is connected to the QB node QB.

A gate electrode of the seventh stage transistor Ts7 is connected to a drain electrode of the third stage transistor Ts3, a source electrode of the seventh stage transistor Ts7 is connected to the second clock signal Clk2, and a drain electrode of the seventh stage transistor Ts7 is connected to the QB node QB.

A gate electrode of the eighth stage transistor Ts8 is connected to the gate low voltage Vgl, a source electrode of the eighth stage transistor Ts8 is connected to a drain electrode of the third stage transistor Ts3, a source electrode of the fourth stage transistor Ts4, and a gate electrode of the seventh stage transistor Ts7, and a drain electrode of the eighth stage transistor Ts8 is connected to the Q node Q.

The first capacitor C1 is connected between the gate electrode and the drain electrode of the first stage transistor Ts1, and the second capacitor C2 is connected between the QB node QB and the gate high voltage Vgh.

In FIG. 7, the (n)th stage SRS(n) of the shift register SR of the first gate driving unit 124 of the display device 110 according to a first embodiment of the invention is driven by dividing one frame into eighth to tenth periods TP8 to TP10.

During the eighth period TP8, the first clock signal Clk1 has a logic high voltage Vh, and the (n-1)th scan2 signal Sc2(n-1) and the second clock signal Clk2 have a logic low voltage Vl. As a result, the third, sixth and eighth stage transistors Ts3, Ts6, and Ts8 are turned on, and the fourth stage transistor Ts4 is turned off. Since a Q node voltage Vq and a QB node voltage Vqb become a logic low voltage Vl, the first, second, fifth, and seventh stage transistors Ts1, Ts2, Ts5, and Ts7 are turned on, and the (n)th scan2 signal Sc2(n) becomes a logic high voltage Vh (or gate high voltage Vgh).

During the ninth period TP9, the second clock signal Clk2 and the (n-1)th scan2 signal Sc2(n-1) have a logic high voltage Vh, and the first clock signal Clk1 has a logic low voltage Vl. As a result, the fourth and eighth stage transistors Ts4 and Ts8 are turned on, and the third and sixth stage transistors Ts3 and Ts6 are turned off. Since the Q node voltage Vq becomes a second logic low voltage Vl2 and the QB node voltage Vqb becomes a logic high voltage Vh, the first and seventh stage transistors Ts1 and Ts7 are turned on and the second and fifth stage transistors Ts2 and Ts5 are turned off. Accordingly, the (n)th scan2 signal Sc2(n) becomes a logic low voltage Vl (or gate low voltage Vgl).

During the tenth period TP10, the first clock signal Clk1 and the (n-1)th scan2 signal Sc2(n-1) have a logic high voltage Vh, and the second clock signal Clk2 has a logic low voltage Vl. As a result, the third, sixth and eighth stage transistors Ts3, Ts6 and Ts8 are turned on, and the fourth stage transistor Ts4 is turned off. Since the Q node voltage Vq becomes a logic high voltage Vh and the QB node voltage Vqb becomes a logic low voltage Vl, the second and fifth stage transistors Ts2 and Ts5 are turned on and the first and seventh stage transistors Ts1 and Ts7 are turned off. Accordingly, the (n)th scan2 signal Sc2(n) becomes a logic high voltage Vh (or gate high voltage Vgh).

The (n)th stage SRS(n) of the shift register SR of the first gate driving unit 124 of the display device 110 according to a first embodiment of the invention generates the (n)th scan2 signal Sc2(n) using the first and second clock signals Clk1 and Clk2, the start signal Vst or the (n-1)th scan2 signal Sc2(n-1), the gate high voltage Vgh and the gate low voltage Vgl and applies the (n)th scan2 signal Sc2(n) to the gate electrode of the third transistor T3 of each subpixel SP1 to SP4 of the (n)th horizontal pixel line of the display panel 128.

In the display device 110 according to a first embodiment of the invention, the first clock signal Clk1 is supplied to the shift register SR and the inverter INV by disposing only one clock link line CLL in the bending area BA, and the inverter INV at a lower portion of the bending area BA generates the second clock signal Clk2 by inverting the first clock signal Clk1 to supply the second clock signal Clk2 to the shift register SR. As a result, the probability of deterioration, such as a crack of the clock link line CLL in the bending area BA, is reduced while the substrate is folded.

In another embodiment, the inverter INV may be disposed at a lower portion of the shift register SR.

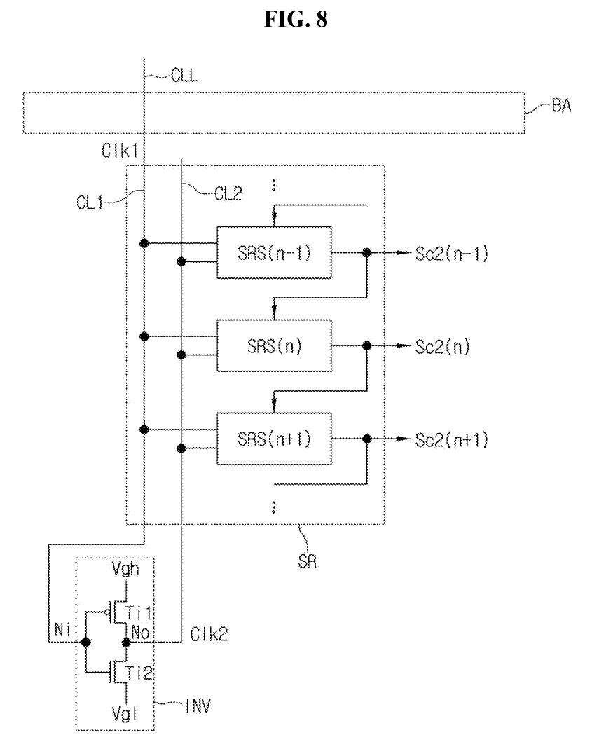

FIG. 8 is a view showing a shift register of a gate driving unit of a display device according to a second embodiment of the invention. Illustration on a part the same as that of a first embodiment will be omitted.

In FIGS. 1 and 8, a first gate driving unit 124 is disposed in a non-display area NDA of a display device 110 according to a second embodiment of the invention. The first gate driving unit 124 includes a shift register SR generating a scan2 signal Sc2, and the shift register SR includes a plurality of stages SRS(n-1), SRS(n) and SRS(n+1) connected to each other in a cascade type.

Each of the plurality of stages SRS(n-1), SRS(n) and SRS(n+1) sequentially generates a plurality of scan2 signals Sc2(n-1), Sc2(n) and Sc2(n+1) using first and second clock signals Clk1 and Clk2, a start signal Vst (FIG. 6) or the scan2 signal Sc2(n-1), Sc2(n) and Sc2(n+1) as an output signal of a previous stage, a gate high voltage Vgh and a gate low voltage Vgl and transmits the plurality of scan2 signals Sc2(n-1), Sc2(n) and Sc2(n+1) to a third transistor T3 of each subpixel SP1 to SP4 of a display panel 128.

For example, an (n)th stage SRS(n) may generate an (n)th scan2 signal Sc2(n) using an (n-1)th scan2 signal Sc2(n-1) as an output signal of an (n-1)th stage SRS(n-1), the gate high voltage Vgh and the gate low voltage Vgl and may apply the (n)th scan2 signal Sc2(n) to a gate electrode of the third transistor T3 of each subpixel SP1 to SP4 of an (n)th horizontal pixel line of the display panel 128.

Here, an inverter INV is disposed in the non-display area NDA at a lower portion of a bending area BA and the shift register SR of the first gate driving unit 124, and the inverter INV includes first and second inverter transistors Ti1 and Ti2.

The first inverter transistor Ti1 is a positive (P) type. A gate electrode of the first inverter transistor Ti1 is connected to an input terminal Ni of the inverter INV, a source electrode of the first inverter transistor Ti1 is connected to the gate high voltage Vgh, and a drain electrode of the first inverter transistor Ti1 is connected to an output terminal No of the inverter INV.

The second inverter transistor Ti2 is a negative (N) type. A gate electrode of the second inverter transistor Ti2 is connected to the input terminal Ni of the inverter INV, a source electrode of the second inverter transistor Ti2 is connected to the gate low voltage Vgl, and a drain electrode of the second inverter transistor Ti2 is connected to the output terminal No of the inverter INV.

The inverter INV generates the second clock signal Clk2 having an inverted shape of the first clock signal Clk1 using the first clock signal Clk1 transmitted from a timing controlling unit 120 through a clock link line CLL and a first clock line CL1 and transmits the second clock signal Clk2 to the plurality of stages SRS(n-1), SRS(n) and SRS(n+1) of the shift register SR through a second clock line CL2.

The clock link line CLL connected to the timing controlling unit 120 is connected to a first end of the first clock line CL1 through the bending area BA.

The first clock line CL1 extends to the inverter INV along a side portion of the shift register SR to be connected to each of the plurality of stages SRS(n-1), SRS(n) and SRS(n+1), and a second end of the first clock line CL1 is connected to the input terminal Ni of the inverter INV.

A first end of the second clock line CL2 is connected to the output terminal No of the inverter INV, and the second clock line CL2 extends along a side portion of the shift register SR to be connected to each of the plurality of stages SRS(n-1), SRS(n) and SRS(n+1).

As a result, the first clock signal Clk1 of the timing controlling unit 120 is supplied to the plurality of stages SRS(n-1), SRS(n) and SRS(n+1) of the shift register SR through the clock link line CLL and the first clock line CL1.

Further, the first clock signal Clk1 of the timing controlling unit 120 is supplied to the inverter INV through the clock link line CLL and the first clock line CL1. The inverter INV generates the second clock signal Clk2 by inverting the first clock signal Clk1, and the second clock signal Clk2 of the inverter INV is supplied to the plurality of stages SRS(n-1), SRS(n) and SRS(n+1) of the shift register SR through the second clock line CL2.

Since only one clock link line CLL is disposed in the bending area BA for supplying the first clock signal Clk1 to the inverter INV and the shift register SR, a probability of deterioration such as a crack of the clock link line CLL in the bending area BA is reduced while the substrate is folded.

In the display device 110 according to a second embodiment of the invention, the first clock signal Clk1 is supplied to the shift register SR and the inverter INV by disposing only one clock link line CLL in the bending area BA, and the inverter INV at a lower portion of the bending area BA generates the second clock signal Clk2 by inverting the first clock signal Clk1 to supply the second clock signal Clk2 to the shift register SR. As a result, the probability of deterioration, such as a crack of the clock link line CLL in the bending area BA, is reduced while the substrate is folded.

In another embodiment, two clock link lines transmitting the first clock signal Clk1 may be disposed in the bending area BA.

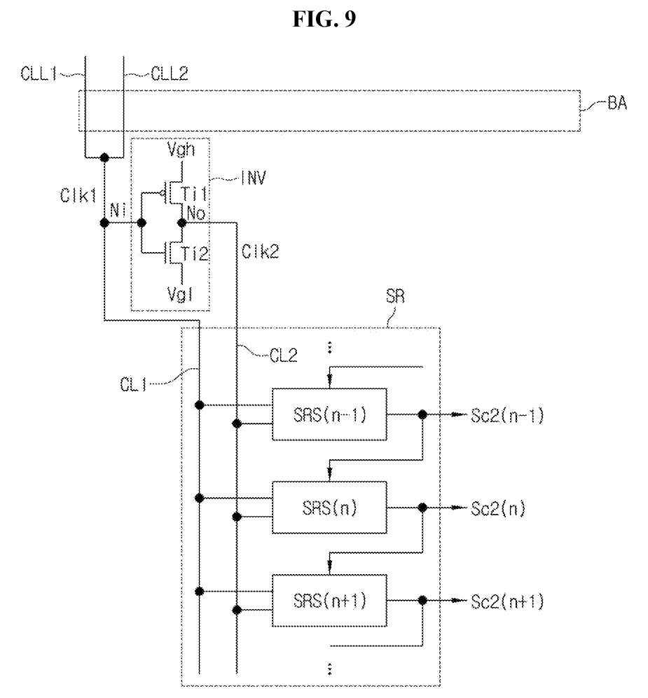

FIG. 9 is a view showing a shift register of a gate driving unit of a display device according to a third embodiment of the invention. Illustration on a part the same as that of first and second embodiments will be omitted.

In FIGS. 1 and 9, a first gate driving unit 124 is disposed in a non-display area NDA of a display device 110 according to a third embodiment of the invention. The first gate driving unit 124 includes a shift register SR generating a scan2 signal Sc2, and the shift register SR includes a plurality of stages SRS(n-1), SRS(n) and SRS(n+1) connected to each other in a cascade type.

Each of the plurality of stages SRS(n-1), SRS(n) and SRS(n+1) sequentially generates a plurality of scan2 signals Sc2(n-1), Sc2(n) and Sc2(n+1) using first and second clock signals Clk1 and Clk2, a start signal Vst (FIG. 6) or the scan2 signal Sc2(n-1), Sc2(n) and Sc2(n+1) as an output signal of a previous stage, a gate high voltage Vgh and a gate low voltage Vgl and transmits the plurality of scan2 signals Sc2(n-1), Sc2(n) and Sc2(n+1) to a third transistor T3 of each subpixel SP1 to SP4 of a display panel 128.

For example, an (n)th stage SRS(n) may generate an (n)th scan2 signal Sc2(n) using an (n-1)th scan2 signal Sc2(n-1) as an output signal of an (n-1)th stage SRS(n-1), the gate high voltage Vgh and the gate low voltage Vgl and may apply the (n)th scan2 signal Sc2(n) to a gate electrode of the third transistor T3 of each subpixel SP1 to SP4 of an (n)th horizontal pixel line of the display panel 128.

Here, an inverter INV is disposed in the non-display area NDA between the shift register SR of the first gate driving unit 124 and a bending area BA, and the inverter INV includes first and second inverter transistors Ti1 and Ti2.

The first inverter transistor Ti1 is a positive (P) type. A gate electrode of the first inverter transistor Ti1 is connected to an input terminal Ni of the inverter INV, a source electrode of the first inverter transistor Ti1 is connected to the gate high voltage Vgh, and a drain electrode of the first inverter transistor Ti1 is connected to an output terminal No of the inverter INV.

The second inverter transistor Ti2 is a negative (N) type. A gate electrode of the second inverter transistor Ti2 is connected to the input terminal Ni of the inverter INV, a source electrode of the second inverter transistor Ti2 is connected to the gate low voltage Vgl, and a drain electrode of the second inverter transistor Ti2 is connected to the output terminal No of the inverter INV.

The inverter INV generates the second clock signal Clk2 having an inverted shape of the first clock signal Clk1 using the first clock signal Clk1 transmitted from a timing controlling unit 120 through first and second clock link lines CLL1 and CLL2 and transmits the second clock signal Clk2 to the plurality of stages SRS(n-1), SRS(n) and SRS(n+1) of the shift register SR through a second clock line CL2.

The first and second clock link lines CLL1 and CLL2 connected to the timing controlling unit 120 extend to the inverter INV through the bending area BA to be connected to the input terminal Ni of the inverter INV and a first end of the first clock line CL1.

The first clock line CL1 connected to the first and second clock link lines CLL1 and CLL2 extends along a side portion of the shift register SR to be connected to each of the plurality of stages SRS(n-1), SRS(n) and SRS(n+1).

A first end of the second clock line CL2 is connected to the output terminal No of the inverter INV, and the second clock line CL2 extends along a side portion of the shift register SR to be connected to each of the plurality of stages SRS(n-1), SRS(n) and SRS(n+1).

As a result, the first clock signal Clk1 of the timing controlling unit 120 is supplied to the plurality of stages SRS(n-1), SRS(n) and SRS(n+1) of the shift register SR through the first and second clock link lines CLL1 and CLL2 and the first clock line CL1.

Further, the first clock signal Clk1 of the timing controlling unit 120 is supplied to the inverter INV through the first and second clock link lines CLL1 and CLL2. The inverter INV generates the second clock signal Clk2 by inverting the first clock signal Clk1, and the second clock signal Clk2 of the inverter INV is supplied to the plurality of stages SRS(n-1), SRS(n) and SRS(n+1) of the shift register SR through the second clock line CL2.

The first and second clock link lines CLL1 and CLL2 are disposed in the bending area BA for supplying the first clock signal Clk1 to the inverter INV and the shift register SR. Even when one of the first and second clock link lines CLL1 and CLL2 has deterioration, such as a crack during a substrate folding, the first clock signal Clk1 is supplied to the inverter INV and the shift register SR through the other having no deterioration of the first and second clock link lines CLL1 and CLL2.

In the display device 110 according to a third embodiment of the invention, the first and second clock link lines CLL1 and CLL2 functioning as a redundancy are disposed in the bending area BA, and the inverter INV at a lower portion of the bending area BA generates the second clock signal Clk2 by inverting the first clock signal Clk1 to supply the second clock signal Clk2 to the shift register SR. As a result, even when one of the first and second clock link lines CLL1 and CLL2 has deterioration, such as a crack during a substrate folding, the first clock signal Clk1 is supplied to the inverter INV and the shift register SR through the other having no deterioration of the first and second clock link lines CLL1 and CLL2, and deterioration is minimized.

Embodiments of the invention provide a display device where deterioration of a clock link line in a bending area is prevented by generating a gate signal using a second clock signal generated from a first clock signal of one clock link line in the bending area of a non-display area through an inverter.

In addition, embodiments of the invention provide a display device where deterioration of a clock link line in a bending area is minimized and a low power consumption is obtained by generating a gate signal using a second clock signal generated from a first clock of a plurality of clock link lines in the bending area of a non-display area through an inverter.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a timing controller configured to generate an image data, a data control signal, and a gate control signal;
a data driver configured to generate a data signal using the image data and the data control signal;
a gate driver configured to generate a gate signal using the gate control signal;
a first clock link line transmitting a first clock signal from the timing controller to the gate driver;
an inverter configured to generate a second clock signal by inverting the first clock signal and to transmit the second clock signal to the gate driver; and
a display panel displaying an image using the data signal and the gate signal and having a display area and a non-display area surrounding the display area,
wherein:
the non-display area includes a bending area as a reference of folding;
the timing controller and the data driver are disposed in the non-display area at an upper portion of the bending area;
the gate driver and the inverter are disposed in the non-display area at a lower portion of the bending area; and
the first clock link line extends from the non-display area at the upper portion of the bending area to the non-display area at the lower portion of the bending area through the bending area.

2. The display device of claim 1, further comprising:
a first clock line transmitting the first clock signal to the gate driver; and
a second clock line transmitting the second clock signal to the gate driver.

3. The display device of claim 2, wherein:
the inverter is disposed between the bending area and the gate driver;
the first clock link line is connected to an input terminal of the inverter and a first end of the first clock line; and
a first end of the second clock line is connected to an output terminal of the inverter.

4. The display device of claim 2, wherein:
the inverter is disposed at a lower portion of the gate driver;
the first clock link line is connected to a first end of the first clock line;
a second end of the first clock line is connected to an input terminal of the inverter; and
a first end of the second clock line is connected to an output terminal of the inverter.

5. The display device of claim 2, further comprising a second clock link line transmitting the first clock signal from the timing controller to the gate driver,
wherein the second clock link line extends from an upper portion of the bending area to the non-display area at a lower portion of the bending area through the bending area.

6. The display device of claim 5, wherein:
the inverter is disposed between the bending area and the gate driver;
the first and second clock link lines are connected to an input terminal of the inverter and a first end of the first clock line; and
a first end of the second clock line is connected to an output terminal of the inverter.

7. The display device of claim 1, wherein:
the display panel includes a plurality of subpixels in the display area; and
each of the plurality of subpixels comprises:
a first transistor switched according to a voltage of a first node and connected to second and third nodes;
a second transistor switched according to a first scan signal and connected to the first and second nodes;
a third transistor switched according to a second scan signal and connected to the third node and the data signal;
a fourth transistor switched according to a second emission signal and connected to the second node and a high level signal;
a fifth transistor switched according to a first emission signal and connected to the third node and a fourth node;
a sixth transistor switched according to the first emission signal and connected to the fourth node and an initial signal;
a storage capacitor connected to the first and fourth nodes; and
a light emitting diode connected to the fourth node and a low level signal.

8. The display device of claim 7, wherein:
a gate electrode of the first transistor, a source electrode of the second transistor, and a first capacitor electrode of the storage capacitor constitute the first node;
a drain electrode of the first transistor, a drain electrode of the second transistor, and a drain electrode of the fourth transistor constitute the second node;
a source electrode of the first transistor, a source electrode of the third transistor, and a source electrode of the fifth transistor constitute the third node; and
a drain electrode of the fifth transistor, a drain electrode of the sixth transistor, and a second capacitor electrode of the storage capacitor constitute the fourth node.

9. The display device of claim 1, wherein:
the gate signal includes a first scan signal, a second scan signal, a first emission signal, and a second emission signal;
the gate driver includes first and second gate drivers at both side portions of the display panel;
the first gate driver includes a second scan block configured to generate the second scan signal and a second emission block configured to generate the second emission signal; and
the second gate driver includes a first scan block configured to generate the first scan signal and a first emission block configured to generate the first emission signal.

10. The display device of claim 9, wherein the second scan block comprises:
a first stage transistor switched according to a voltage of a Q node and connected to the first clock signal and a second stage transistor;
the second stage transistor switched according to a voltage of a QB node and connected to the first stage transistor and a gate high voltage;
a third stage transistor switched according to the second clock signal and connected to one of a start signal and an (n-1)th second scan signal and a Q2 node;
a fourth stage transistor switched according to the first clock signal and connected to the Q2 node and a fifth stage transistor;
the fifth stage transistor switched according to the voltage of the QB node and connected to the fourth stage transistor and the gate high voltage;
a sixth stage transistor switched according to the second clock signal and connected to a gate low voltage and the QB node;
a seventh stage transistor switched according to a voltage of the Q2 node and connected to the second clock signal and the QB node; and
an eighth stage transistor switched according to the gate low voltage and connected to the Q2 node and the Q node.
